(19) United States
(12) Patent Application Publication
(10) Pub. No.: US 2025/0255043 A1
(43) Pub. Date: Aug. 7, 2025

(54) LIGHT-EMITTING ELEMENT AND VISUAL INSPECTION METHOD

(71) Applicant: NIKKISO CO., LTD., Tokyo (JP)

(72) Inventors: Kazuyoshi SAKURAGI, Ishikawa (JP); Hidemasa TOMOZAWA, Ishikawa (JP)

(73) Assignee: NIKKISO CO., LTD., Tokyo (JP)

(21) Appl. No.: 19/041,105

(22) Filed: Jan. 30, 2025

(30) Foreign Application Priority Data
Feb. 1, 2024 (JP) 2024-014080

(51) Int. Cl. H10H 20/831; H01L 21/66; H10H 20/832

(52) U.S. Cl. CPC H10H 20/831; H01L 22/12; H10H 20/835

(57) ABSTRACT

A light-emitting element includes an n-type semiconductor layer, an active layer formed on the n-type semiconductor layer, a p-type semiconductor layer formed on the active layer, a p-side electrode formed on the p-type semiconductor layer, and an n-side electrode formed on the n-type semiconductor layer. At least one of the p-side electrode and the n-side electrode includes an observation hole that allows observation of the light-emitting element from both upper and lower sides.

### CROSS-REFERENCE TO RELATED APPLICATIONS

The present application is based on Japanese patent application No. 2024-014080 filed on Feb. 1, 2024, the entire contents of which are incorporated herein by reference.

### TECHNICAL FIELD

The present invention relates to a light-emitting element and a visual inspection method.

### BACKGROUND OF THE INVENTION

Patent Literature 1 discloses a visual inspection method for a light-emitting device. In the visual inspection method described in Patent Literature 1, whether or not a light-emitting element has a defect is determined based on the brightness of the surroundings of the light-emitting device when made emit light.

Citation List Patent Literature 1: JP 2017-20983 A

### SUMMARY OF THE INVENTION

In the visual inspection method described in Patent literature 1, whether or not a defect is present cannot be determined unless power is supplied to make the light-emitting device emit light.

The invention was made in view of such circumstances and it is an object of the invention to provide a light-emitting element and a visual inspection method that allow for easy visual inspection.

To achieve the object described above, the invention provides a light-emitting element, comprising:
an n-type semiconductor layer;
an active layer formed on the n-type semiconductor layer;
a p-type semiconductor layer formed on the active layer;
a p-side electrode formed on the p-type semiconductor layer; and
an n-side electrode formed on the n-type semiconductor layer,
wherein at least one of the p-side electrode and the n-side electrode comprises an observation hole that allows observation of the light-emitting element from both upper and lower sides.

To achieve the object described above, the invention provides a visual inspection method for visually inspecting whether or not a light-emitting element has a defect, the light-emitting element comprising an n-type semiconductor layer, an active layer formed on the n-type semiconductor layer, a p-type semiconductor layer formed on the active layer, a p-side electrode formed on the p-type semiconductor layer and an n-side electrode formed on the n-type semiconductor layer, and at least one of the p-side electrode and the n-side electrode comprising an observation hole that allows observation of the light-emitting element from both upper and lower sides, the method comprising: evaluating the light-emitting element by comparing a size of the observation hole with a size of a defect observed when viewing the light-emitting element respectively from the upper and lower sides.

### Advantageous Effects of the Invention

According to the invention, it is possible to provide a light-emitting element and a visual inspection method that allow for easy visual inspection.

### BRIEF DESCRIPTION OF DRAWINGS

FIG. 1 is a plan view showing a light-emitting element in the first embodiment.

FIG. 2 is a bottom view showing the light-emitting element in the first embodiment.

FIG. 3 is a cross-sectional view taking along line III-III of FIG. 1, as viewed in an arrow direction.

FIG. 4 is a cross-sectional view showing a first intermediate body in the first embodiment.

FIG. 5 is a cross-sectional view showing a second intermediate body in the first embodiment.

FIG. 6 is a cross-sectional view showing a third intermediate body in the first embodiment.

FIG. 7 is a cross-sectional view showing a fourth intermediate body in the first embodiment.

FIG. 8 is a cross-sectional view showing a fifth intermediate body in the first embodiment.

FIG. 9 is a plan view showing the light-emitting element in the second embodiment.

FIG. 10 is a plan view showing the light-emitting element in the third embodiment.

### DETAILED DESCRIPTION OF THE INVENTION

### First Embodiment

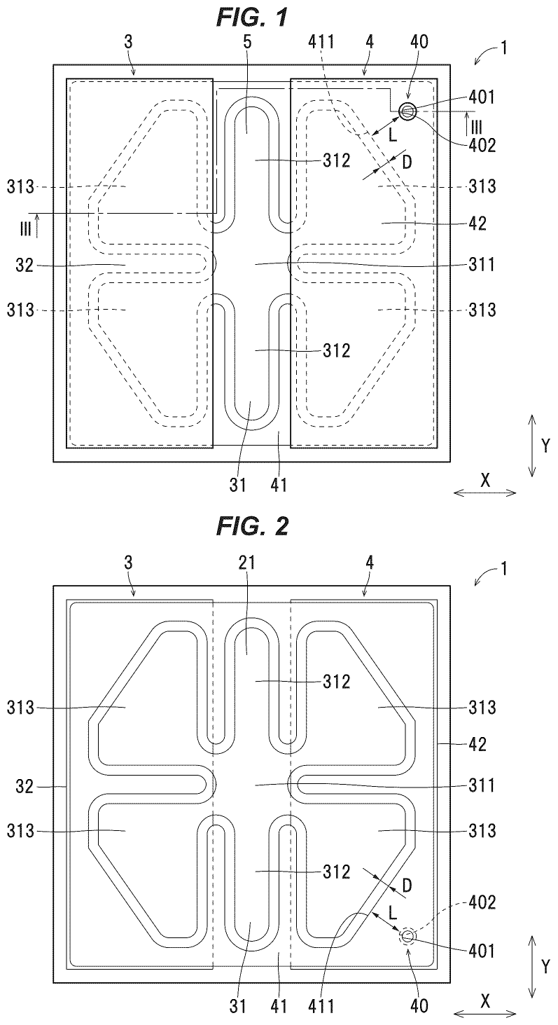

The first embodiment of the invention will be described in reference to the FIGS. 1 to 8. The embodiment below is described as a preferred illustrative example for implementing the invention. Although some part of the embodiment specifically illustrates various technically preferable matters, the technical scope of the invention is not limited to such specific aspects.

### Light-Emitting Element 1

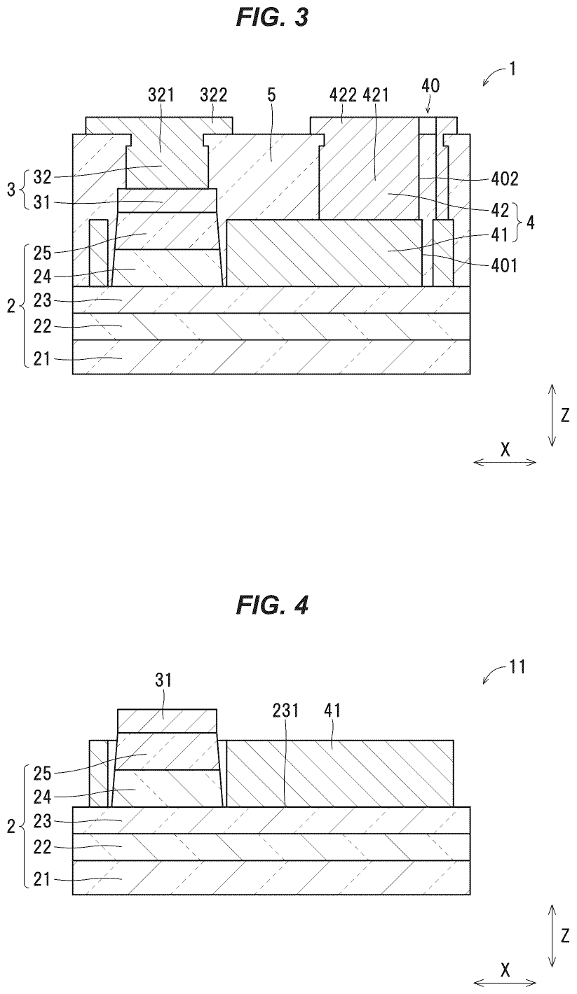

FIG. 1 is a plan view showing a light-emitting element 1 in the first embodiment. FIG. 2 is a bottom view showing the light-emitting element 1. FIG. 3 is a cross-sectional view taking along line III-III of FIG. 1, as viewed in an arrow direction. In FIGS. 1 and 2, portions that are not present on the outermost surface but can be seen through a transparent member are indicated by thin solid lines, and portions that are hidden behind a non-transparent member and cannot be seen are indicated by dashed lines.

The light-emitting element 1 in the first embodiment is, e.g., a light-emitting diode (LED) or a semiconductor laser (LD: laser diode). The light-emitting element 1 can be, e.g., a deep ultraviolet LED emitting deep ultraviolet light and can be used in fields such as sterilization (e.g., air purification, water purification, etc.), medical treatment (e.g., light therapy, measurement/analysis, etc.), UV curing, etc. The light-emitting element 1 in the first embodiment includes a stacked structure 2, a p-side electrode 3, an n-side electrode 4, and a covering member 5.

As shown in FIG. 3, the stacked structure 2 has a substrate 21, a buffer layer 22, an n-type semiconductor layer 23, an active layer 24, and a p-type semiconductor layer 25, in this order. Hereinafter, the stacking direction of the stacked structure 2 will be referred to as the up-and-down direction Z, the p-type semiconductor layer 25 side relative to the n-type semiconductor layer 23 will be referred to as the upper side, and the opposite side will be referred to as the lower side. In this regard, the terms “upper” and “lower” are used for descriptive purposes and do not limit the posture of the light-emitting element 1 with respect to the vertical direction when, e.g., the light-emitting element 1 is used. The light-emitting element 1 has a quadrilateral outer shape when viewed in the up-and-down direction Z, and directions along this outer shape will be referred to as the horizontal direction X (e.g., the left-right direction in FIGS. 1 and 2) and the vertical direction Y (e.g., the up-and-down direction in FIGS. 1 and 2).

The substrate 21 has a property of transmitting light (deep ultraviolet light in the first embodiment) emitted by the active layer 24. The substrate 21 can be, e.g., a sapphire (Al₂O₃) substrate. Alternatively, e.g., an aluminum nitride (AlN) substrate or an aluminum gallium nitride (AlGaN) substrate, etc., may be used as the substrate 21.

As semiconductors constituting the buffer layer 22, the n-type semiconductor layer 23, the active layer 24 and the p-type semiconductor layer 25, it is possible to use, e.g., binary to quaternary group III nitride semiconductors expressed by AlₓGa_{y}In_{1-x-y}N (0≤x≤1, 0≤y≤1, 0≤x+y≤1). In deep ultraviolet LEDs, Al_{z}Ga_{1-z}N system (0≤z≤1) not including indium is often used.

The buffer layer 22 is formed on the substrate 21. The buffer layer 22 is made of undoped AlₐGa₁₋ₐN (0≤a≤1). As an example, the buffer layer 22 has an AlN layer made of aluminum nitride (i.e., a=1) and formed on the substrate 21, and an AlGaN layer made of undoped aluminum gallium nitride (i.e., 0<a<1) and formed on the AlN layer. However, the buffer layer 22 is not limited thereto, and may be a single layer or may be composed of not less than three layers. When the substrate 21 is an aluminum nitride substrate or an aluminum gallium nitride substrate, the buffer layer 22 may not be necessarily included.

The n-type semiconductor layer 23 is formed on the buffer layer 22. The n-type semiconductor layer 23 is made of Al_{b}Ga_{1-b}N (0≤b≤1) doped with an n-type impurity. The n-type semiconductor layer 23 may have a single-layer structure or may have a multilayer structure.

The active layer 24 is formed on a portion of an upper surface of the n-type semiconductor layer 23. The active layer 24 is made of Al_{c}Ga_{1-c}N (0≤c≤1) and can have, e.g., a single quantum well structure having one well layer, or a multiple quantum well structure having plural well layers. In the active layer 24, electrons supplied from the n-type semiconductor layer 23 recombine with holes supplied from the p-type semiconductor layer 25, resulting in light emission. The active layer 24 is configured to have a band gap of not less than 3.4 eV so that deep ultraviolet light at a wavelength of not more than 365 nm is output. For example, the central wavelength of the light emitted by the active layer 24 can be not less than 200 nm and not more than 365 nm. The active layer 24 may be a layer that emits deep ultraviolet light at a central wavelength of not more than 290 nm.

The p-type semiconductor layer 25 is formed on the active layer 24. The p-type semiconductor layer 25 is made of Al_{d}Ga_{1-d}N (0≤d≤1) doped with a p-type impurity. The p-type semiconductor layer 25 may have a single-layer structure or may have a multilayer structure.

In the first embodiment, side surfaces of the active layer 24 and the p-type semiconductor layer 25 are inclined so that the widths of the active layer 24 and the p-type semiconductor layer 25 become narrower toward the upper side. That is, the n-type semiconductor layer 23, the active layer 24 and the p-type semiconductor layer 25 form a mesa structure. In addition, in the stacked structure 2, at least the substrate 21, the buffer layer 22 and the n-type semiconductor layer 23 are transparent to visible light.

The p-side electrode 3 includes a p-side contact electrode 31 in ohmic contact with an upper surface of the p-type semiconductor layer 25, and a p-side pad electrode 32 formed on the p-side contact electrode 31 and electrically connected to a mounting substrate (e.g., a submount substrate, etc.) on which the light-emitting element 1 is mounted. Meanwhile, the n-side electrode 4 has an n-side contact electrode 41 in ohmic contact with a region of an upper surface of the n-type semiconductor layer 23 where the active layer 24 is not formed, and an n-side pad electrode 42 formed on the n-side contact electrode 41 and electrically connected to the mounting substrate on which the light-emitting element 1 is mounted. The p-side electrode 3 and the n-side electrode 4 are opaque to visible light (i.e., colored).

As shown in FIGS. 1 and 2, the p-side contact electrode 31 has a central portion 311, two vertical extension portions 312 extending from the central portion 311 on both sides in the vertical direction Y, and four diagonal extension portions 313 extending from the central portion 311 in four directions along the diagonals of the outer shape of the light-emitting element 1. The p-side contact electrode 31 is electrically connected to the p-side pad electrode 32 at, e.g., two diagonal extension portions 313 located on the left side in FIG. 1.

The p-type semiconductor layer 25 and the active layer 24 located under the p-side contact electrode 31 are formed in a region overlapping the p-side contact electrode 31 in the up-and-down direction Z. That is, the p-type semiconductor layer 25 and the active layer 24 have the same outer shape as the p-side contact electrode 31 when viewed in the up-and-down direction Z.

In the first embodiment, the light-emitting element 1 when used is flip-chip mounted on the mounting substrate, and light is extracted mainly from the substrate 21 side. Then, the p-side contact electrode 31 has a reflective electrode that reflects light emitted from the active later 24. The reflectance of the reflective electrode to the light emitted from the active layer 24 is, e.g., not less than 50%, preferably not less than 80%. The reflective electrode can include, e.g., a layer made of rhodium (Rh). When the p-side contact electrode 31 includes the reflective electrode and the p-type semiconductor layer 25 includes a p-type contact layer made of p-type GaN, a film thickness of the p-type contact layer is preferably thin and is, e.g., not more than 20 nm. P-type GaN absorbs light relatively easily, but by reducing the film thickness of the p-type contact layer made of p-type GaN, light reflected at the p-side contact electrode 31 is likely to be extracted from the substrate 21 side and light output of the light-emitting element 1 is likely to be improved. In this regard, the p-side contact electrode 31 may not include the reflective electrode. The p-side contact electrode 31 may have a single film structure or may have a multi-film structure. In addition, the light-emitting element 1 may be face-up mounted on the mounting substrate so that light is extracted from the side opposite to the substrate 21.

The n-side contact electrode 41 is formed to surround the p-side contact electrode 31 with a certain space D when viewed in the up-and-down direction Z. The outer contour shape of the n-side contact electrode 41 is a quadrilateral shape along the outer contour shape of the light-emitting element 1. The n-side contact electrode 41 is electrically connected to the n-side pad electrode 42 at, e.g., a portion located on the right side in FIG. 1. An observation hole 40 is formed in the n-side contact electrode 41 and the n-side pad electrode 42, which will be described later.

Each of the p-side contact electrode 31 and the n-side contact electrode 41, except for the observation hole 40, has a rotationally symmetric shape. In particular, each of the p-side contact electrode 31 and the n-side contact electrode 41, except for the observation hole 40, is formed to have 180° rotational symmetry.

The p-side pad electrode 32 and the n-side pad electrode 42 are formed side by side in the horizontal direction X. The p-side pad electrode 32 is electrically connected to the p-side contact electrode 31 and the n-side pad electrode 42 is electrically connected to the n-side contact electrode 41.

As shown in FIG. 3, the p-side pad electrode 32 has a p-side buried portion 321 buried in the covering member 5, and a p-side exposed portion 322 exposed from the covering member 5 and electrically connected to the mounting substrate on which the light-emitting element 1 is mounted. The n-side pad electrode 42 has an n-side buried portion 421 buried in the covering member 5, and an n-side exposed portion 422 exposed from the covering member 5 and electrically connected to the mounting substrate. The light-emitting element 1 is electrically connected to electrodes of the mounting substrate at the p-side exposed portion 322 and the n-side exposed portion 422 through connection members such as bumps made of gold (Au), etc.

As shown in FIGS. 1 to 3, at least one of the p-side electrode 3 and the n-side electrode 4 has the observation hole 40 which allows observation of the light-emitting element 1 from both the upper and lower sides. In the first embodiment, the observation hole 40 is formed at one location in the n-side electrode 4 and is not formed in the p-side electrode 3, as shown in FIGS. 1 and 2. The p-type semiconductor layer 25 and the active layer 24 are not present under the n-side electrode 4, unlike the p-side electrode 3. Therefore, the visibility of the observation hole 40 when viewed from the lower side is better when the observation hole 40 is formed in the n-side electrode 4. If the observation hole 40 is formed in the p-side electrode 3, a connection hole connected to the observation hole 40 can be formed in the p-type semiconductor layer 25 and the active layer 24 so that the visibility of the observation hole 40 is improved through this connection hole, but this reduces the area of the active layer 24 and may cause a decrease in output of the light-emitting element 1. Also from such a viewpoint, it is preferable to form the observation hole 40 in the n-side electrode 4. In addition, although detailed illustration is omitted, in case where the number of layers constituting the n-side electrode 4 is smaller than the number of layers constituting the p-side electrode 3, it is easier to form the observation hole 40 with good dimensional accuracy when forming the observation hole 40 in the n-side electrode 4. In addition, in the first embodiment, the p-side electrode 3 has the reflective electrode. In such a case, if the observation hole 40 is formed in the p-side electrode 3, the area of the p-side electrode 3 is reduced by the area of the observation hole 40 and the total amount of light that can be reflected is also reduced. Therefore, it is preferable to form the observation hole 40 in the n-side electrode 4 also from the viewpoint of improving light output.

As shown in FIGS. 1 to 3, the observation hole 40 has a first hole portion 401 formed in the n-side contact electrode 41, and a second hole portion 402 formed in the n-side pad electrode 42. The first hole portion 401 is a column-shaped hole having a circular shape in a cross section orthogonal to the up-and-down direction Z. The second hole portion 402 is a column-shaped hole having a circular shape with a larger diameter than that of the first hole portion 401 in a cross section orthogonal to the up-and-down direction Z. Both the first hole portion 401 and the second hole portion 402 are observed when viewing the light-emitting element 1 from the upper side as shown in FIG. 1, and only the first hole portion 401 is observed when viewing the light-emitting element 1 from the lower side as shown in FIG. 2. At least one of the first hole portion 401 and the second hole portion 402 may be formed in, e.g., a tapered shape such that the diameter decreases toward the lower side.

The observation hole 40 provided in the light-emitting element 1 can be used as a criterion for defect determination in a visual inspection of the light-emitting element 1. In the visual inspection of the light-emitting element 1, whether or not a defect of not less than a predetermined determination criterion size is present when viewing the light-emitting element 1 from both the upper and lower sides is checked, and the observation hole 40 is designed so that a portion with the smallest inner diameter (i.e., a portion where the light-emitting element 1 can be observed from both the upper and lower sides) has the predetermined determination criterion size. This facilitates the visual inspection since the light-emitting element 1 and an index of the determination criterion size (i.e., the observation hole 40) are present together in the field of view during the visual inspection. The details of the visual inspection will be described later.

Here, as shown in FIG. 2, the entire light-emitting element 1, except for the observation hole 40, has a rotationally symmetric shape when viewed from a side opposite to a side where it is mounted on the mounting substrate (i.e., viewed from the lower side). The entire light-emitting element 1, except for the observation hole 40, when viewed from the lower side has a 180° rotationally symmetric shape in the first embodiment, but is not limited thereto and may have a rotationally symmetric shape other than 180°, such as 90° rotationally symmetric shape. The observation hole 40 is formed so that the light-emitting element 1 has a rotationally asymmetric shape when viewing the light-emitting element 1 from the lower side. For example, when the observation hole 40 is formed to have a circular cross section as in the first embodiment, the observation hole 40 is formed at a position off the central position of the light-emitting element 1 when viewed from the lower side. As a result, by checking the position of the observation holes 40 from a side of the light-emitting element 1 opposite to the mounting substrate after mounting the light-emitting element 1 on the mounting substrate, it is possible to determine whether the light-emitting element 1 is mounted on the mounting substrate in a desired rotational orientation or incorrectly mounted in an orientation rotated 180° from the desired rotational orientation.

As shown in FIGS. 1 and 2, the observation hole 40 when viewed in the up-and-down direction Z is formed at a position away from an edge 411 of the n-side contact electrode 41 on the p-side contact electrode 31 side at a distance greater than the space D between the n-side contact electrode 41 and the p-side contact electrode 31. That is, the space D and a shortest distance L between the observation hole 40 and the edge 411 of the n-side contact electrode 41 when viewed in the up-and-down direction Z satisfy a relationship L>D. In the first embodiment, the observation hole 40 is formed in a portion that is close to a corner of the n-side contact electrode 41 and occupies a relatively large area in the n-side contact electrode 41.

As shown in FIG. 3, the covering member 5 covers and protects the light-emitting element 1. The covering member 5 is transparent to visible light and is made of an inorganic material that is electrically insulating and difficult for moisture to penetrate. The covering member 5 is made of, e.g., silicon dioxide (SiO₂), silicon nitride (SiN), or silicon carbide (SiC), etc. The covering member 5 covers, e.g., at least a surface of the light-emitting element 1 on the lower side of the p-side exposed portion 322 and the n-side exposed portion 422 and on the upper side of the n-type semiconductor layer 23. The covering member 5 also fills the inside of the observation hole 40 up to below the p-side exposed portion 322 and the n-side exposed portion 422.

### Method for Manufacturing the Light-Emitting Element 1

Next, an example of a method for manufacturing the light-emitting element 1 in the first embodiment will be described.

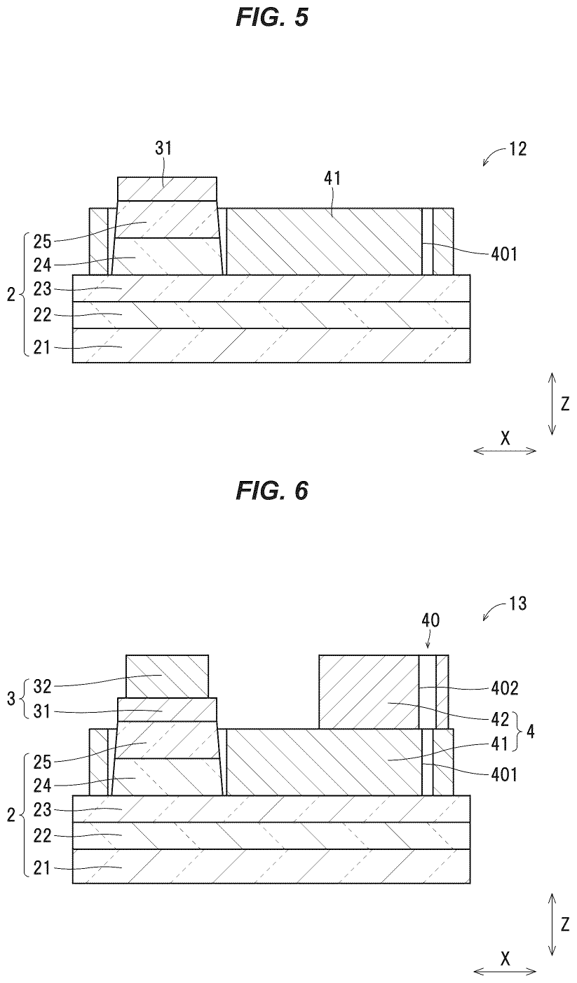

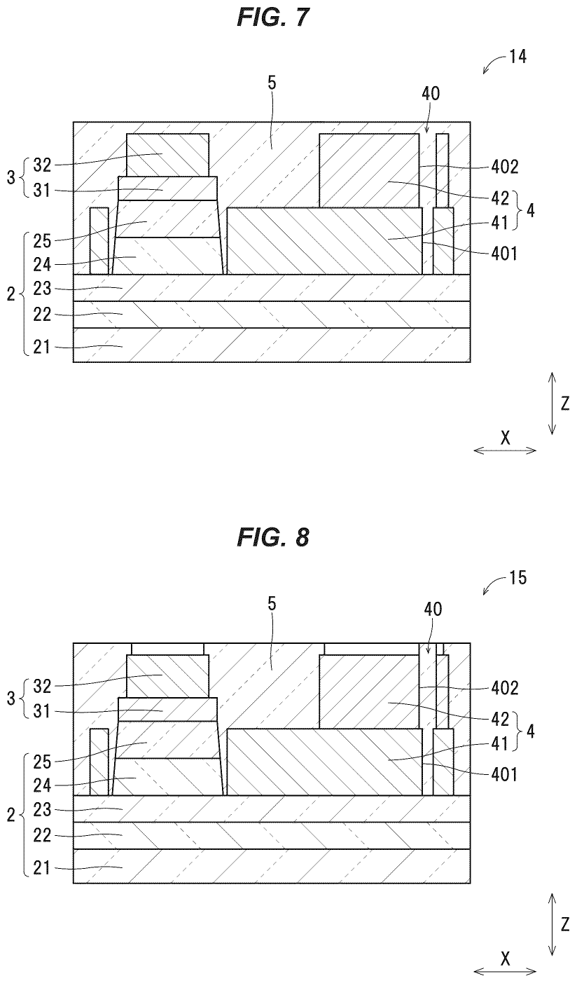

The method for manufacturing the light-emitting element 1 includes a semiconductor film deposition step, a first etching step, a contact electrode formation step, a second etching step, a first step of pad electrode formation, a covering step, and a second step of pad electrode formation. FIG. 4 is a cross-sectional view showing a first intermediate body 11 obtained after the semiconductor film deposition step, the first etching step, and the contact electrode formation step. FIG. 5 is a cross-sectional view showing a second intermediate body 12 obtained after the second etching step. FIG. 6 is a cross-sectional view showing a third intermediate body 13 obtained after the first step of pad electrode formation. FIG. 7 is a cross-sectional view showing a fourth intermediate body 14 obtained in the middle of the covering step. FIG. 8 is a cross-sectional view showing a fifth intermediate body 15 obtained after the covering step.

In the semiconductor film deposition step, first, the buffer layer 22, the n-type semiconductor layer 23, the active layer 24 and the p-type semiconductor layer 25 are formed on the substrate 21 using a well-known epitaxial growth method such as the Metal Organic Chemical Vapor Deposition (MOCVD) method, the Molecular Beam Epitaxy (MBE) method, or the Hydride Vapor Phase Epitaxy (HVPE) method, as shown in FIG. 4. The manufacturing conditions for epitaxially growing each semiconductor layer, such as growth temperature, growth pressure and growth time, etc., can be general conditions according to the configuration of each semiconductor layer.

After the semiconductor film deposition step, the first etching step is performed. In the first etching step, after forming the buffer layer 22, the n-type semiconductor layer 23, the active layer 24 and the p-type semiconductor layer 25 on the substrate 21, a mask (not shown) is formed on a predetermined portion of the upper surface of the p-type semiconductor layer 25. Then, the p-type semiconductor layer 25 and the active layer 24 formed at positions not overlapping the mask are removed by etching. An exposed upper surface 231 exposed from the active layer 24 is thereby formed on the n-type semiconductor layer 23. After forming the exposed upper surface 231, the mask is removed.

After the first etching step, the contact electrode formation step is performed. In the contact electrode formation step, for example, the p-side contact electrode 31 is first formed on the p-type semiconductor layer 25 and the n-side contact electrode 41 is then formed on the exposed upper surface 231 of the n-type semiconductor layer 23. In the first embodiment, the n-side contact electrode 41 not having the first hole portion 401 is formed first. The p-side contact electrode 31 and the n-side contact electrode 41 can be formed by, e.g., a well-known method such as electron beam evaporation method or sputtering method using a photolithography technique. The first intermediate body 11 shown in FIG. 4 is obtained in the contact electrode formation step.

After the contact electrode formation step, the second etching step is performed. In the second etching step, the first hole portion 401 is formed in the n-side contact electrode 41 by etching. The second intermediate body 12 shown in FIG. 5 is obtained in the second etching step.

After the second etching step, the first step of pad electrode formation is performed. In the first step of pad electrode formation, the p-side pad electrode 32 and the n-side pad electrode 42, except for upper end portions thereof, are formed. In the first step of pad electrode formation, the p-side pad electrode 32 and the n-side pad electrode 42, except for the upper end portions thereof, are formed by vapor deposition using the photolithography technique. In this regard, when forming the n-side contact electrode 41, the n-side contact electrode 41 not having the first hole portion 401 is formed first and the first hole portion 401 is then formed by etching. However, when forming the n-side pad electrode 42, the n-side pad electrode 42 having the second hole portion 402 already therein is formed by the photolithography technique. The third intermediate body 13 shown in FIG. 6 is obtained in the first step of pad electrode formation.

After the first step of pad electrode formation, the covering step is performed. In the covering step, the upper part of the third intermediate body 13 is covered with the covering member 5 made of an inorganic material such as silicon dioxide by using, e.g., a well-known technique such as the Chemical Vapor Deposition (CVD) method. At this time, the covering member 5 also fills the inside of the observation hole 40. The covering member 5 is formed up to a position on the upper side relative to the p-side pad electrode 32 and the n-side pad electrode 42 that are formed in the first step of pad electrode formation. The fourth intermediate body 14 shown in FIG. 7 is obtained in the covering step.

Then, portions of the covering member 5 in the fourth intermediate body 14 at positions where the p-side pad electrode 32 and the n-side pad electrode 42 are to be formed are removed by etching, etc., and the fifth intermediate body 15 shown in FIG. 8 is thereby obtained.

After the covering step, the second step of pad electrode formation is performed. In the second step of pad electrode formation, the upper end portions of the p-side pad electrode 32 and the n-side pad electrode 42 are formed. In the second step of pad electrode formation, the upper end portions of the p-side pad electrode 32 and the n-side pad electrode 42 are formed by vapor deposition using the photolithography technique. Also in the second step of pad electrode formation, when forming the n-side pad electrode 42, the n-side pad electrode 42 having the second hole portion 402 already therein is formed, in the same manner as the first step.

A wafer with a large number of light-emitting elements 1 is completed through the above steps, and a large number of light-emitting elements 1 as shown in FIGS. 1 to 3 are singulated by dividing the wafer by stealth dicing, etc.

The light-emitting element 1 in the first embodiment can be manufactured as described above.

### Method for Visual Inspection of Light-Emitting Element 1

Next, an example of visual inspection performed after manufacturing the light-emitting element 1 will be described. The visual inspection can be performed, e.g., after manufacturing the light-emitting element 1 and before mounting it on a mounting substrate, and after mounting the light-emitting element 1 on the mounting substrate and before testing the characteristics of the light-emitting element 1.

In the visual inspection before mounting the light-emitting element 1 on a mounting substrate, the light-emitting element 1 is viewed from both the upper and lower sides to check whether or not any defects of not less than a predetermined determination criterion size exist. Meanwhile, in the visual inspection after mounting the light-emitting element 1 on the mounting substrate, the light-emitting element 1 is viewed from the opposite side to the mounting substrate to check whether or not any defects of not less than the predetermined determination criterion size exist. Then, light-emitting elements 1 having a defect of not less than the determination criterion size are determined to be defective products, and light-emitting elements 1 with no defect of not less than the determination criterion size are determined to be acceptable products. Acceptable products are carried on to the next process for, e.g., shipment, whereas defective products are not carried on to the next process and are, e.g., discarded.

Defects to be checked in the visual inspection can include, e.g., point defect, line defect, hillock, die chipping, die scratching, pattern delamination, etc. Point defect, line defect and hillock are defects formed in the stacked structure 2 of the light-emitting element 1. Die chipping can be formed when, e.g., a corner of the substrate 21 hits an object and is chipped. Die scratching can be formed as scratches caused by, e.g., an object rubbing against the lower surface of the substrate 21. Pattern delamination can be formed when the p-side electrode 3 and the n-side electrode 4 partially come off.

In the example of the first embodiment, the determination criterion size is assumed to be the same for the various types of defects described above. The determination criterion size can be, e.g., not more than 50 μm, but is appropriately designed according to the requirements in each case. The light-emitting element 1 in the first embodiment is formed so that the smallest inner diameter of the observation hole 40 (the inner diameter of the first hole portion 401 in the first embodiment) is the same as the determination criterion size. Since this results in that the observation hole 40 of the same size as the determination criterion size is present in the light-emitting element 1 itself within the field of view during the visual inspection, whether the light-emitting element 1 passes or fails the visual inspection can be easily determined by comparing the inner diameter of the observation hole 40 with the size of the defect. As a result, a sample, etc., of a light-emitting element in which a defect having a size equivalent to the determination criterion size is formed does not need to be prepared separately from the light-emitting element to be inspected.

Determination by the visual inspection may be made by visual observation using a microscope, etc., or may be made automatically using an automatic inspection device. In case of making a determination using an automatic inspection device, if there is no observation hole 40 (i.e., the index of the determination criterion size), an image of the light-emitting element 1 with a defect having the determination criterion size needs to be pre-registered in the automatic inspection device for comparison, but it is difficult to create a defect of an intended size in the light-emitting element 1. When the observation hole 40 serving as an index of the determination criterion size is formed in the light-emitting element 1 as in the first embodiment, it is not necessary to create a defect of an intended size, and the above-mentioned registration can be easily performed. Therefore, using the light-emitting element 1 in the first embodiment can increase efficiency of not only the visual inspection by visual observation but also the visual inspection using an automatic inspection device.

### Functions and Effects of the First Embodiment

In the light-emitting element 1 of the first embodiment, at least one of the p-side electrode 3 and the n-side electrode 4 has the observation hole 40 which allows observation of the light-emitting element 1 from both the upper and lower sides. Thus, it is possible to use the size of the observation hole 40 as a criterion for determining whether the light-emitting element 1 has a defect in a visual inspection of the light-emitting element 1.

In addition, the observation hole 40 is formed in the n-side electrode 4. The p-type semiconductor layer 25 and the active layer 24 are not present under the n-side electrode 4, unlike the p-side electrode 3. Therefore, the visibility of the observation hole 40 when viewed from the lower side is better when the observation hole 40 is formed in the n-side electrode 4. If the observation hole 40 is formed in the p-side electrode 3, a connection hole connected to the observation hole 40 can be formed in the p-type semiconductor layer 25 and the active layer 24 so that the visibility of the observation hole 40 is improved through this connection hole, but this reduces the area of the active layer 24 and may cause a decrease in output of the light-emitting element 1. Also from such a viewpoint, it is preferable to form the observation hole 40 in the n-side electrode 4. In addition, in case where the number of layers constituting the n-side electrode 4 is smaller than the number of layers constituting the p-side electrode 3, it is easier to form the observation hole 40 with good dimensional accuracy when forming the observation hole 40 in the n-side electrode 4. In addition, in the first embodiment, the p-side electrode 3 has the reflective electrode. In such a case, if the observation hole 40 is formed in the p-side electrode 3, the area of the p-side electrode 3 is reduced by the area of the observation hole 40 and the total amount of light that can be reflected is also reduced. Therefore, it is preferable to form the observation hole 40 in the n-side electrode 4 also from the viewpoint of improving light output.

In addition, when viewed in the up-and-down direction Z, the p-side contact electrode 31 and the n-side contact electrode 41 are formed with the space D therebetween. Then, the observation hole 40 when viewed in the up-and-down direction Z is formed at a position away from the edge 411 of the n-side contact electrode 41 on the p-side contact electrode 31 side at a distance greater than the space D. This makes it easier to form the observation hole 40 with good dimensional accuracy. If the observation hole 40 is formed in a region close to the p-side contact electrode 31, the dimensional accuracy of the observation hole 40 may decrease by, e.g., being affected by the active layer 24 and the p-type semiconductor layer 25 at the time of vapor deposition or etching, etc. when forming the observation hole 40.

In addition, the cross-sectional shape of the observation hole 40 orthogonal to the up-and-down direction Z is a circular shape. This allows the observation hole 40 to be formed small. It is difficult to form the observation hole 40 unless an area of a portion of the electrode (the n-side electrode 4 in the first embodiment) where the observation hole 40 is formed is large to some extent. However, the observation hole 40 is small and this suppresses an increase in the size of the electrode and therefore suppresses an increase in the size of the light-emitting element 1.

In addition, the light-emitting element 1, except for the observation hole 40, has a rotationally symmetric shape when viewed from a side opposite to a side where it is mounted on the mounting substrate, and the observation hole 40 is formed so that the light-emitting element 1 has a rotationally asymmetric shape when viewing the light-emitting element 1 from the side opposite to the side where it is mounted on the mounting substrate. Therefore, whether or not the light-emitting element 1 is mounted on the mounting substrate in a desired orientation can be determined before conducting electrical characteristic test. Particularly in the first embodiment, the observation hole 40 is formed at a position off the central position of the light-emitting element 1 when viewed from the side opposite to the side where it is mounted on the mounting substrate. Therefore, whether or not the light-emitting element 1 is mounted on the mounting substrate in a desired orientation can be determined based on the position of the observation hole 40.

As described above, according to the first embodiment, it is possible to provide a light-emitting element and a visual inspection method that allow for easy visual inspection.

### Second Embodiment

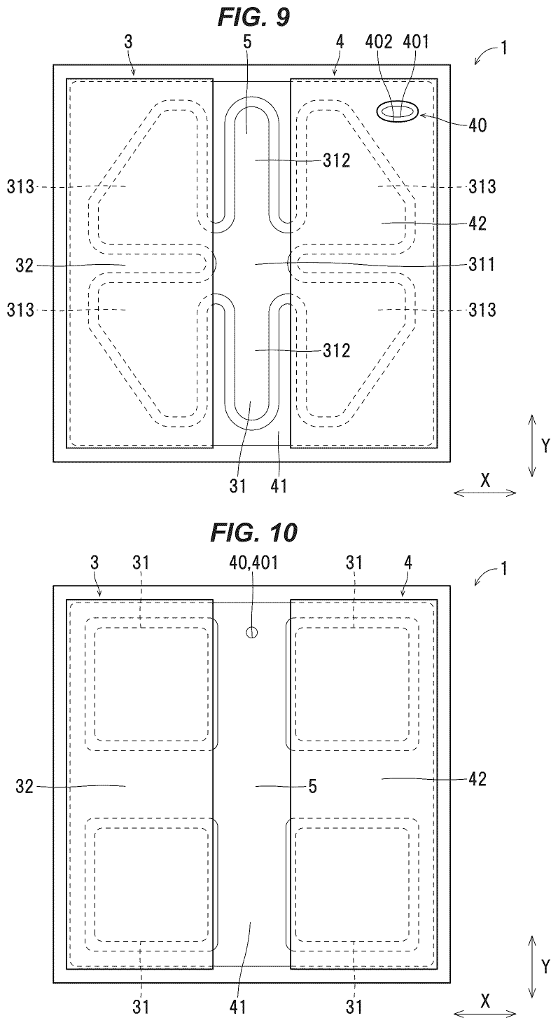

The second embodiment of the invention will be described in reference to the FIG. 9. FIG. 9 is a plan view showing the light-emitting element 1 in the second embodiment.

The second embodiment is an embodiment in which the shape of the observation hole 40 is changed with respect to that in the first embodiment. In the second embodiment, a cross-sectional shape of the observation hole 40 orthogonal to the up-and-down direction Z is a shape that is long in one direction. In particular, the cross-sectional shape of the observation hole 40 orthogonal to the up-and-down direction Z is an elliptical shape that is long in the horizontal direction X. The observation hole 40 has the first hole portion 401 formed in a relatively small elliptical shape, and the second hole portion 402 formed in an elliptical shape slightly larger than the first hole portion 401. However, the cross-sectional shape of the observation hole 40 is not limited to that described above, and can be another long shape such as a rectangle, a rectangle with rounded corners, or a rhombus.

The other configurations are the same as in the first embodiment.

Among the reference numerals used in the second embodiment onwards, the same reference numerals as those used in the already-described embodiments indicate the same constituent elements, etc., as those in the already-described embodiments, unless otherwise specified.

### Functions and Effects of the Second Embodiment

In the second embodiment, the cross-sectional shape of the observation hole 40 orthogonal to the up-and-down direction Z is a shape that is long in one direction. Therefore, it is possible to use, e.g., the dimension of the observation hole 40 in the major axis direction (i.e., the horizontal direction X) and the dimension of the observation hole 40 in the minor axis direction (i.e., the vertical direction Y) as criteria for the visual inspection of light-emitting element 1. As a result, in a case where, e.g., the allowable size differs depending on the type of defect, it is possible to indicate two size criteria with one observation hole 40. In addition, when, e.g., the determination criterion size for defects allowed in the light-emitting element 1 is changed from the dimension of the observation hole 40 in the minor axis direction to the dimension of the observation hole 40 in the major axis direction, the determination criterion size after the change is still indicated by the observation hole 40, hence, it is possible to perform the visual inspection substantially without being affected by the change in the determination criterion size. For example, circular observation holes of different sizes from each other may be formed, but in comparison with such a case, complexity in manufacturing of the light-emitting element 1 can be suppressed in the second embodiment since one observation hole 40 can represent two determination criterion sizes.

The other functions and effects are the same as in the first embodiment.

### Third Embodiment

The third embodiment of the invention will be described in reference to the FIG. 10. FIG. 10 is a plan view showing the light-emitting element 1 in the third embodiment.

The third embodiment is an example in which the shapes of the p-side contact electrode 31 and the n-side contact electrode 41 are changed with respect to those in the first embodiment. In the third embodiment, the p-side contact electrodes 31 are formed at four locations so as to be arranged in two rows and two columns in the horizontal direction X and the vertical direction Y when viewed in the up-and-down direction Z. Each p-side contact electrode 31 is formed in a quadrilateral shape along the horizontal direction X and the vertical direction Y. The n-side contact electrode 41 when viewed in the up-and-down direction Z is formed in a grid pattern that surrounds the p-side contact electrodes 31 with a certain space.

Each of the p-side contact electrode 31 and the n-side contact electrode 41, except for the observation hole 40, has a rotationally symmetric shape. In particular, each of the p-side contact electrode 31 and the n-side contact electrode 41, except for the observation hole 40, is formed to have 90° rotational symmetry.

In the third embodiment, the observation hole 40 is formed only in the n-side contact electrode 41. The observation hole 40 is formed at a position between the p-side pad electrode 32 and the n-side pad electrode 42 when viewed in the up-and-down direction Z (i.e., at a position not overlapping the p-side pad electrode 32 and the n-side pad electrode 42 in the up-and-down direction Z).

In addition, the entire light-emitting element 1, except for the observation hole 40, has a rotationally symmetric shape (in particular, 180° rotational symmetry) when viewed from a side opposite to a side where it is mounted on the mounting substrate (i.e., viewed from the lower side). Then, the observation hole 40 is formed so that the light-emitting element 1 has a rotationally asymmetric shape when viewing the light-emitting element 1 from the lower side. In the third embodiment, the observation hole 40 is formed at a position offset to one side in the vertical direction Y.

The other configurations are the same as in the first embodiment.

### Functions and Effects of the Third Embodiment

In the third embodiment, since the observation hole 40 is formed in the n-side contact electrode 41 at a position not overlapping the n-side pad electrode 42 in the up-and-down direction Z, it is easy to form the observation hole 40.

The other configurations are the same as in the first embodiment.

### MODIFICATIONS

Other possible modifications of the light-emitting element will be described.

The examples in which the first hole portion is formed to be relatively small and the second hole portion relatively large have been described in the first and second embodiments. However, it is not limited thereto. For example, the first hole portion may be formed to be relatively large and the second hole portion relatively small. In this case, the inner diameter of the second hole portion is designed to be a determination criterion size for the visual inspection. Alternatively, the first hole portion and the second hole portion may be of the same size. In this case, however, it is difficult to form the observation hole with good dimensional accuracy. That is, in this case, since the first hole portion and the second hole portion need to be formed to have the same inner diameter and also need to be formed without misalignment in the vertical and horizontal directions, it is difficult to make the observation hole with good dimensional accuracy. For this reason, the configuration is preferably such that, e.g., the second hole portion is formed to be larger than the first hole portion and the first hole portion is located within the second hole portion when viewed in the up-and-down direction, or vice versa.

In addition, the observation hole is formed at only one location in the first and second embodiments. However, it is not limited thereto and observation holes may be formed at plural locations. When there are plural determination criterion sizes for the visual inspection of the light-emitting element, plural observation holes are formed respectively in accordance with the plural determination criterion sizes.

In addition, the observation hole is formed at a position off the central position of the light-emitting element when viewed in the up-and-down direction in the first to third embodiments. However, it is not limited thereto.

In addition, the shape of the observation hole can also be changed in various ways. For example, the shape of the observation hole may be a cross shape with different dimensions in the vertical and horizontal directions, or a T shape, etc. The same functions and effects as those in the second embodiment are thereby obtained.

In addition, by forming the observation hole so as to have a rotationally asymmetric shape when viewed in the up-and-down direction, it is possible to determine the rotational orientation of the light-emitting element regardless of the position of the observation hole. For example, in case of the cross shape, by forming the observation hole in a rotationally asymmetric cross shape with the horizontal bar located close to the top of the vertical bar, the observation hole can be used as the index to determine the rotational orientation of the light-emitting element even when the observation hole is located at the central position of the light-emitting element. Similarly, also in case of forming the observation hole in a T shape, the observation hole can be used as the index to determine the rotational orientation of the light-emitting element even when the observation hole is located at the central position of the light-emitting element.

### SUMMARY OF THE EMBODIMENTS

Technical ideas understood from the embodiments will be described below citing the reference signs, etc., used for the embodiments. However, each reference sign, etc., described below is not intended to limit the constituent elements in the claims to the members, etc., specifically described in the embodiments.

The first embodiment relating to the invention is a light-emitting element 1 comprising: an n-type semiconductor layer 23; an active layer 24 formed on the n-type semiconductor layer 23; a p-type semiconductor layer 25 formed on the active layer 24; a p-side electrode 3 formed on the p-type semiconductor layer 25; and an n-side electrode 4 formed on the n-type semiconductor layer 23, wherein at least one of the p-side electrode 3 and the n-side electrode 4 comprises an observation hole 40 that allows observation of the light-emitting element 1 from both upper and lower sides.

It is thereby possible to facilitate the visual inspection of the light-emitting element 1.

The second embodiment relating to the invention is that, in the first embodiment, the observation hole 40 is formed in the n-side electrode 4.

It is thereby possible to facilitate the visual inspection of the light-emitting element 1.

The third embodiment relating to the invention is that, in the second embodiment, the p-side electrode 3 comprises a p-side contact electrode 31 in contact with the p-type semiconductor layer 25, and a p-side pad electrode 32 formed on the p-side contact electrode 31, the n-side electrode 4 comprises an n-side contact electrode 41 in contact with the n-type semiconductor layer 23, and an n-side pad electrode 32 formed on the n-side contact electrode 31, the p-side contact electrode 31 and the n-side contact electrode 41 are formed with a space D therebetween when viewed in an up-and-down direction Z, and the observation hole 40 when viewed in the up-and-down direction Z is formed at a position away from an edge 411 of the n-side contact electrode 41 on the p-side contact electrode 31 side at a distance greater than the space D.

This makes it easier to form the observation hole 40 with good dimensional accuracy.

The fourth embodiment relating to the invention is that, in the second or third embodiment, the p-side electrode 3 comprises a reflective electrode that reflects light emitted from the active layer 24.

A decrease in the total amount of light reflected at the reflective electrode due to forming the observation hole 40 in the reflective electrode is thereby suppressed.

The fifth embodiment relating to the invention is that, in any one of the first to fourth embodiments, a cross-sectional shape of the observation hole 40 orthogonal to the up-and-down direction Z is a circular shape.

This makes it easier to suppress an increase in size of the light-emitting element 1.

The sixth embodiment relating to the invention is that, in any one of the first to fourth embodiments, a cross-sectional shape of the observation hole 40 orthogonal to the up-and-down direction Z is a shape that is long in one direction.

This suppresses complexity in manufacturing of the light-emitting element 1.

The seventh embodiment relating to the invention is that, in any one of the first to sixth embodiments, the light-emitting element 1, except for the observation hole 40, has a rotationally symmetric shape when viewed from a side opposite to a side where the light-emitting element 1 is mounted on a mounting substrate, and the observation hole 40 is formed so that the light-emitting element 1 has a rotationally asymmetric shape when viewed from the side opposite to the side where the light-emitting element 1 is mounted on the mounting substrate.

Whether or not the light-emitting element 1 is mounted on the mounting substrate in a desired orientation can thereby be easily determined.

The eighth embodiment relating to the invention is that, in the seventh embodiment, the observation hole 40 is formed at a position off a central position of the light-emitting element 1 when viewed from the side opposite to the side where the light-emitting element 1 is mounted on the mounting substrate.

Whether or not the light-emitting element 1 is mounted on the mounting substrate in a desired orientation can thereby be determined based on the position of the observation hole 40.

The ninth embodiment relating to the invention is a visual inspection method for visually inspecting whether or not a light-emitting element 1 has a defect, the light-emitting element 1 comprising an n-type semiconductor layer 23, an active layer 24 formed on the n-type semiconductor layer 23, a p-type semiconductor layer 25 formed on the active layer 24, a p-side electrode 3 formed on the p-type semiconductor layer 25 and an n-side electrode 4 formed on the n-type semiconductor layer 23, and at least one of the p-side electrode 3 and the n-side electrode 4 comprising an observation hole 40 that allows observation of the light-emitting element 1 from both upper and lower sides, the method comprising: evaluating the light-emitting element 1 by comparing a size of the observation hole 40 with a size of a defect observed when viewing the light-emitting element 1 respectively from the upper and lower sides.

This makes it easy to perform the visual inspection of the light-emitting element 1.

### ADDITIONAL NOTE

Although the embodiments of the invention have been described, the invention according to claims is not to be limited to the embodiments described above. Further, please note that not all combinations of the embodiments are necessary to solve the problem of the invention. In addition, the invention can be appropriately modified and implemented without departing from the gist thereof.

1. A light-emitting element, comprising:
an n-type semiconductor layer;
an active layer formed on the n-type semiconductor layer;
a p-type semiconductor layer formed on the active layer;
a p-side electrode formed on the p-type semiconductor layer; and
an n-side electrode formed on the n-type semiconductor layer,
wherein at least one of the p-side electrode and the n-side electrode comprises an observation hole that allows observation of the light-emitting element from both upper and lower sides.

2. The light-emitting element according to claim 1, wherein the observation hole is formed in the n-side electrode.

3. The light-emitting element according to claim 2, wherein the p-side electrode comprises a p-side contact electrode in contact with the p-type semiconductor layer, and a p-side pad electrode formed on the p-side contact electrode, wherein the n-side electrode comprises an n-side contact electrode in contact with the n-type semiconductor layer, and an n-side pad electrode formed on the n-side contact electrode, wherein the p-side contact electrode and the n-side contact electrode are formed with a space therebetween when viewed in an up-and-down direction, and wherein the observation hole when viewed in the up-and-down direction is formed at a position away from an edge of the n-side contact electrode on the p-side contact electrode side at a distance greater than the space.

4. The light-emitting element according to claim 2, wherein the p-side electrode comprises a reflective electrode that reflects light emitted from the active layer.

5. The light-emitting element according to claim 1, wherein a cross-sectional shape of the observation hole orthogonal to the up-and-down direction is a circular shape.

6. The light-emitting element according to claim 1, wherein a cross-sectional shape of the observation hole orthogonal to the up-and-down direction is a shape that is long in one direction.

7. The light-emitting element according to claim 1, wherein the light-emitting element, except for the observation hole, has a rotationally symmetric shape when viewed from a side opposite to a side where the light-emitting element is mounted on a mounting substrate, and wherein the observation hole is formed so that the light-emitting element has a rotationally asymmetric shape when viewed from the side opposite to the side where the light-emitting element is mounted on the mounting substrate.

8. The light-emitting element according to claim 7, wherein the observation hole is formed at a position off a central position of the light-emitting element when viewed from the side opposite to the side where the light-emitting element is mounted on the mounting substrate.

9. A visual inspection method for visually inspecting whether or not a light-emitting element has a defect, the light-emitting element comprising an n-type semiconductor layer, an active layer formed on the n-type semiconductor layer, a p-type semiconductor layer formed on the active layer, a p-side electrode formed on the p-type semiconductor layer and an n-side electrode formed on the n-type semiconductor layer, and at least one of the p-side electrode and the n-side electrode comprising an observation hole that allows observation of the light-emitting element from both upper and lower sides, the method comprising:
evaluating the light-emitting element by comparing a size of the observation hole with a size of a defect observed when viewing the light-emitting element respectively from the upper and lower sides.
